(19) United States
(12) Patent Application Publication
(10) Pub. No.: US 2026/0182033 A1
(43) Pub. Date: Jun. 25, 2026

(54) PIXEL STRUCTURE

(71) Applicant: AUO Corporation, Hsinchu City (TW)

(72) Inventors: Yi-Da He, Hsinchu City (TW); Kuo-Kuang Chen, Hsinchu City (TW)

(73) Assignee: AUO Corporation, Hsinchu City (TW)

(21) Appl. No.: 19/242,967

(22) Filed: Jun. 18, 2025

(30) Foreign Application Priority Data
Dec. 25, 2024 (TW) 113150567

(51) Int. Cl. H10D 86/40; H10D 86/60

(52) U.S. Cl. CPC H10D 86/443; H10D 86/421; H10D 86/471; H10D 86/60

(57) ABSTRACT

A pixel structure disposed on a substrate includes first and second transistors. The first transistor includes a first conductive layer, a first semiconductor layer over the first conductive layer, a first gate over the first semiconductor layer, a first gate insulating layer between the first gate and the first semiconductor layer, and a first source/drain electrically connecting the first semiconductor layer. The second transistor is electrically connected with the first transistor and includes a second semiconductor layer over the first semiconductor layer, a second gate over the second semiconductor layer, a second gate insulating layer between the second gate and the second semiconductor layer, and a second source/drain electrically connecting the second semiconductor layer. An orthographic projection of the second semiconductor layer completely overlaps an orthographic projection of the first conductive layer, and the orthographic projection of the second semiconductor layer is outside an orthographic projection of the first gate.

### CROSS-REFERENCE TO RELATED APPLICATION

This application claims the priority benefit of Taiwan application serial no. 113150567, filed on December 25, 2024. The entirety of the above-mentioned patent application is hereby incorporated by reference herein and made a part of this specification.

### BACKGROUND

### TECHNICAL FIELD

The disclosure relates to a display structure, and particularly relates to a pixel structure.

### DESCRIPTION OF RELATED ART

Thin film transistors are usually disposed in the pixel structure of a display device. The thin film transistors are formed by depositing various thin films (such as semiconductors, metal layers, dielectric layers, etc.) on a substrate to serve as various functional components in the display device, such as a switching element, a driving element, etc. With the continuous advancement of display technologies, the thin film transistors are stacked at different horizontal heights to enhance current driving capability, for example.

However, due to the undulation of the surface resulting from a thin film transistor located at a lower horizontal height, a layer, such as a semiconductor layer, of a thin film transistor at a higher horizontal height is unable to be formed on a flat surface. As a result, such layer may be broken easily in a subsequent process. In such case, the thin film transistor may fail.

### SUMMARY

The disclosure provides a pixel structure capable of preventing a layer of a thin film transistor from breaking.

An embodiment of the disclosure provides a pixel structure. The pixel structure is disposed on a substrate and includes a first transistor and a second transistor. The first transistor includes: a first conductive layer, located over the substrate; a first semiconductor layer, located over the first conductive layer; a first dielectric layer, located between the first semiconductor layer and the first conductive layer; a first gate, located over the first semiconductor layer; a first gate insulating layer, located between the first gate and the first semiconductor layer; and a first source/drain, electrically connected with the first semiconductor layer. The second transistor is electrically connected with the first transistor and includes: a second semiconductor layer, located over the first semiconductor layer; a second gate, located over the second semiconductor layer; a second gate insulating layer, located between the second gate and the second semiconductor layer; and a second source/drain, electrically connected with the second semiconductor layer. An orthographic projection of the second semiconductor layer on the substrate completely overlaps an orthographic projection of the first conductive layer on the substrate, and the orthographic projection of the second semiconductor layer on the substrate is located outside an orthographic projection of the first gate on the substrate.

Another embodiment of the disclosure provides a pixel structure. The pixel structure includes a substrate, multiple subpixels and multiple light-emitting elements. The subpixels are disposed on the substrate, and each of the subpixels includes a first transistor and a second transistor. The first transistor includes: a first conductive layer, located over the substrate; a first semiconductor layer, located over the first conductive layer; a first dielectric layer, located between the first semiconductor layer and the first conductive layer; a first gate, located over the first semiconductor layer; a first gate insulating layer, located between the first gate and the first semiconductor layer; and a first source/drain, electrically connected with the first semiconductor layer. An orthographic projection area of the first semiconductor layer on the substrate is substantially smaller than or equal to an orthographic projection area of the first conductive layer on the substrate. The second transistor is located over the first transistor and electrically connected with the first transistor. The second transistor includes: a second conductive layer, located over the first semiconductor layer; a second semiconductor layer, located over the second conductive layer; a second dielectric layer, located between the second semiconductor layer and the second conductive layer; a second gate, located over the second semiconductor layer; a second gate insulating layer, located between the second gate and the second semiconductor layer; and a second source/drain, electrically connected with the second semiconductor layer. A percentage of an area occupied by the first conductive layer of a first subpixel among the subpixels in the first subpixel is different from a percentage of an area occupied by the first conductive layer of a second subpixel among the subpixels in the second subpixel. Multiple light-emitting elements are respectively disposed in the subpixels and respectively electrically connected with the first transistor or the second transistor.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a pixel structure according to an embodiment of the disclosure.

FIG. 2 is a schematic enlarged view of a subpixel of the pixel structure of FIG. 1.

FIG. 3A is a schematic cross-sectional view taken along a cross-sectional line A-A' of FIG. 2.

FIG. 3B is a schematic cross-sectional view taken along a cross-sectional line B-B' of FIG. 2.

FIG. 4 is a schematic enlarged view of another subpixel of the pixel structure of FIG. 1.

FIG. 5 is a schematic cross-sectional view taken along a cross-sectional line C-C' of FIG. 4.

FIG. 6 is a schematic diagram of a pixel circuit of a subpixel of a pixel structure according to an embodiment of the disclosure.

FIG. 7 is an enlarged schematic view of a second subpixel of a pixel structure according to another embodiment of the disclosure.

FIG. 8A is a schematic cross-sectional view taken along a cross-sectional line D-D' of FIG. 7.

FIG. 8B is a schematic cross-sectional view taken along a cross-sectional line E-E' of FIG. 7.

### DESCRIPTION OF THE EMBODIMENTS

In the drawings, the thickness of layers, films, panels, regions, etc., is enlarged for clarity. Throughout the specification, the same reference numerals denote the same components. It should be understood that when an element such as a layer, a film, a region, or a substrate is indicated to be “on” another element or “connected with” another element, it may be directly on another element or connected with another element, or an element in the middle may exist. Comparatively, when an element is indicated to be “directly on another element” or “directly connected with” another element, an element in the middle does not exist. As used herein, “to connect” may indicate to physically and/or electrically connect. Furthermore, “to electrically connect” or “to couple” may also be used when other elements exist between two elements.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion. Thus, first “element,” “component,” “region,” “layer,” or “portion” discussed below could be termed a second element, component, region, layer, or portion without departing from the teachings herein.

The terminology used herein is for the purpose of describing particular embodiments and is not intended to be limiting of the disclosure. As used herein, the singular forms "a," "an" and "the" are intended to include the plural forms as well, unless the context clearly indicates otherwise. “or” represents “and/or”. The term “and/or” used herein includes any or a combination of one or more of the associated listed items. It will be further understood that the terms "comprises," "comprising," "includes" and/or "including," when used herein, specify the presence of stated features, regions, integers, steps, operations, elements, and/or components, but do not preclude the presence or addition of one or more other features, regions, integers, steps, operations, elements, components, and/or groups thereof. The term "source/drain" as used herein may refer to a source, a drain, or both a source and a drain.

In addition, relative terms such as “below” or “bottom” and “above” or “top” may be used herein to describe a relationship of one element to another element as shown in the figures. It should be understood that the relative terms are intended to encompass different orientations of the device in addition to the orientation depicted in the figures. For example, if the device in a figure is turned over, elements described as being on the “below” side of other elements would be oriented on the “above” side of the other elements. Thus, the exemplary term “below” may encompass both “below” and “above” orientations, depending on the particular orientation of the figure. Similarly, if the device in a figure is turned over, elements described as “beneath” or “below” other elements would be oriented “above” the other elements. Thus, the exemplary terms “beneath” or “below” may encompass both above and below orientations.

The usages of “approximately”, “similar to”, or “substantially” indicated throughout the specification include the indicated value and an average value having an acceptable deviation range, which is a certain value confirmed by people skilled in the art, and is a certain amount considering the discussed measurement and measurement-related deviation (that is, the limitation of measurement system). For example, “approximately” may indicate to be within one or more standard deviations of the indicated value, or being within ±30%, ±20%, ±10%, ±5%. Furthermore, the usages of “approximately”, “similar to”, or “substantially” indicated throughout the specification may refer to a more acceptable deviation range or standard deviation depending on optical properties, etching properties, or other properties, and all properties may not be applied with one standard deviation.

Unless otherwise defined, all terminologies (including technical and scientific terminologies) used herein have the same meaning as commonly understood by people having ordinary skill in the art to which the disclosure belongs. It is understood that these terminologies, such as those defined in commonly used dictionaries, should be interpreted as having meanings consistent with the relevant art and the background or context of the disclosure, and should not be interpreted in an idealized or overly formal way, unless otherwise defined in the embodiments of the disclosure.

Reference is made herein to cross-sectional views as schematic illustrations of idealized embodiments to describe exemplary embodiments. Therefore, variations from the shapes of the illustrations may be expected as a result of, for example, manufacturing techniques and/or tolerances. Thus, embodiments described herein should not be construed as limited to the particular shapes of regions as illustrated herein but include, for example, shape deviations resulting from manufacturing. For example, a region shown or described as flat may typically have rough and/or nonlinear features. Moreover, sharp angles that are illustrated may be rounded. Thus, the regions illustrated in the figures are schematic in nature, and shapes thereof are not intended to illustrate the precise shape of a region and are not intended to limit the scope of the claims.

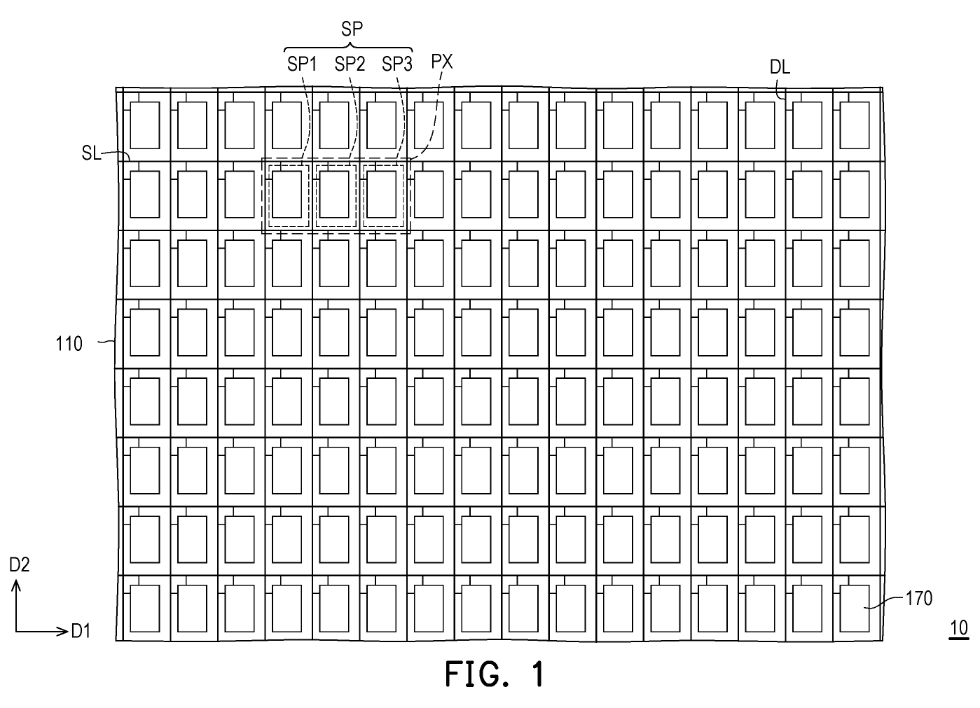

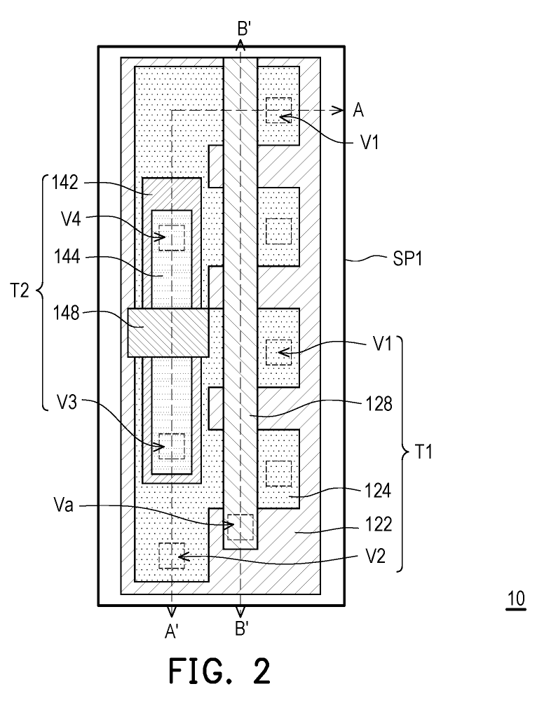

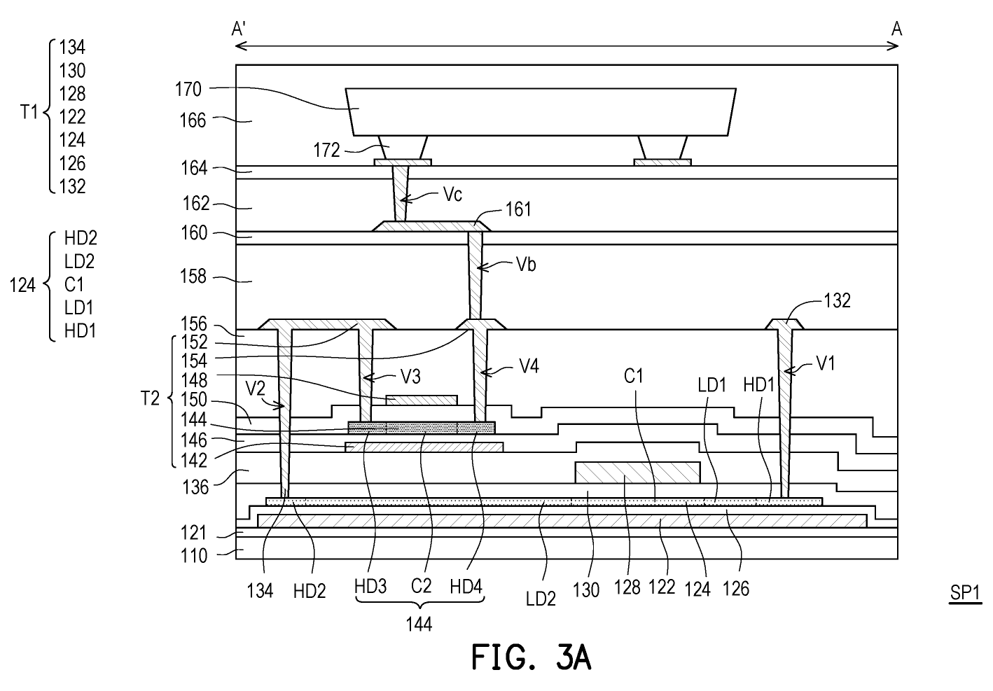

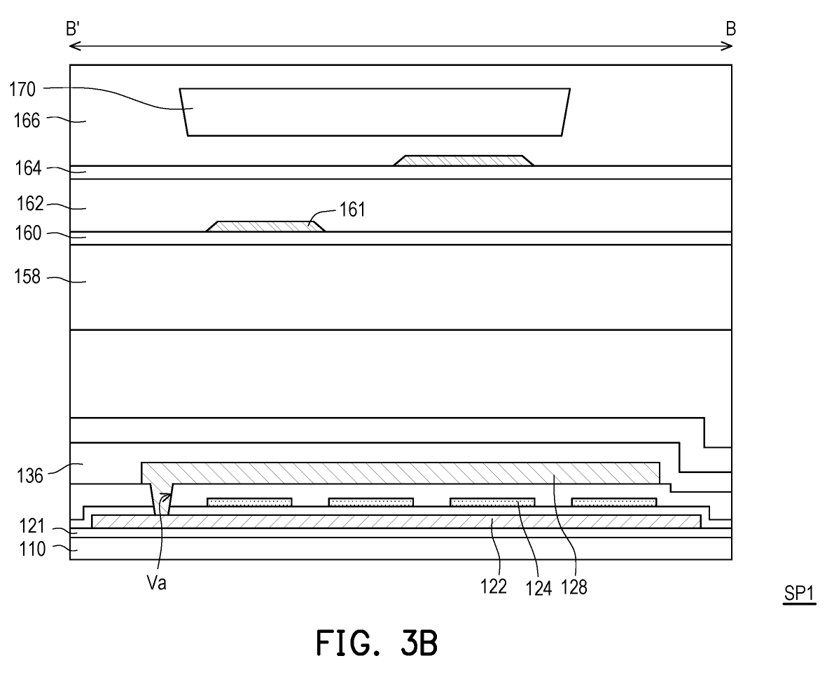

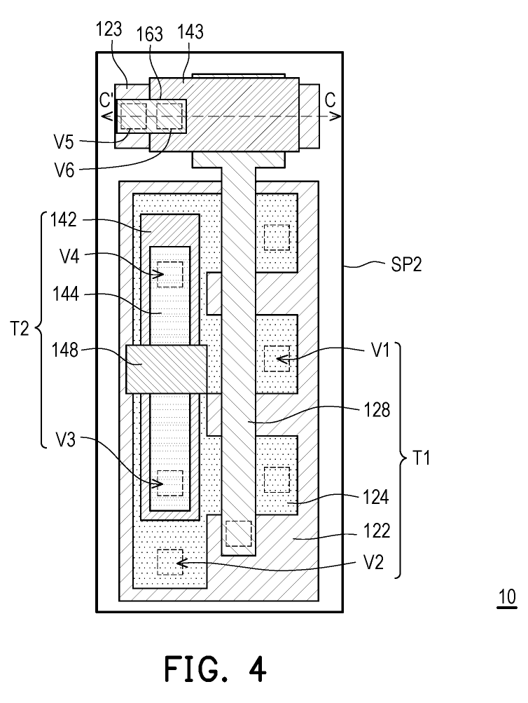

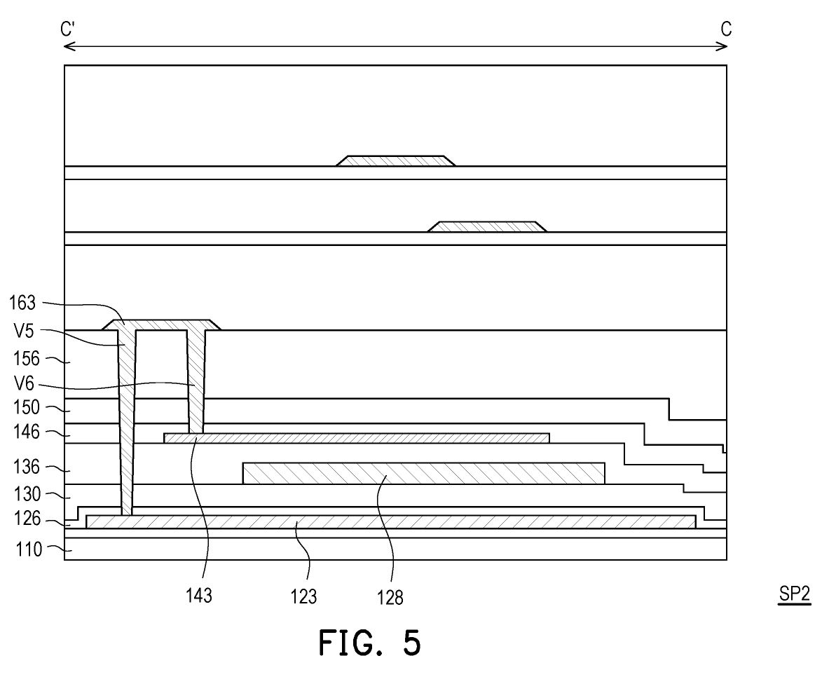

FIG. 1 is a schematic top view of a pixel structure 10 according to an embodiment of the disclosure. FIG. 2 is a schematic enlarged view of a subpixel SP1 of the pixel structure 10 of FIG. 1. FIG. 3A is a schematic cross-sectional view taken along a cross-sectional line A-A' of FIG. 2. FIG. 3B is a schematic cross-sectional view taken along a cross-sectional line B-B' of FIG. 2. FIG. 4 is a schematic enlarged view of another subpixel SP2 of the pixel structure 10 of FIG. 1. FIG. 5 is a schematic cross-sectional view taken along a cross-sectional line C-C' of FIG. 4. For the purpose of clear illustration, some components in FIGS. 2 to 5 are omitted in FIG. 1.

First, referring to FIG. 1, the pixel structure 10 includes a substrate 110, multiple scan lines SL, multiple data lines DL, and multiple subpixels SP. The scan lines SL, the data lines DL, and the subpixels SP are disposed on the substrate 110. The scan lines SL may extend in a direction D1 parallel to each other. The data lines DL may extend in a direction D2 parallel to each other. The scan lines SL and the data lines DL may be interlaced with each other to define regions for disposing the subpixels SP. Each subpixel SP may be electrically connected with a corresponding scan line SL and a corresponding data line DL, respectively. In some embodiments, two adjacent scan lines SL and two adjacent data lines DL are interlaced with each other to surround the region for disposing the subpixel SP.

The subpixels SP may include multiple subpixels SP1, multiple subpixels SP2, and multiple subpixels SP3. For example, the subpixels SP1 may be arranged in the same column along the direction D2, the subpixels SP2 may be arranged in the same column along the direction D2, the subpixels SP3 may be arranged in the same column along the direction D2, and the column of the subpixels SP1, the column of the subpixels SP2, and the column of the subpixels SP3 may be cyclically arranged in sequence along the direction D1. In some embodiments, in the same row along the direction D1, a subpixel SP1, a subpixel SP2, and a subpixel SP3 that are adjacent may form a pixel PX. In addition, for example, the subpixel SP1 may emit red light, the subpixel SP2 may emit blue light, and the subpixel SP3 may emit green light. Through a light mixing effect of the subpixel SP1, the subpixel SP2, and the subpixel SP3, the pixel PX may render various colored light as required.

The substrate 110 may be a transparent substrate or an opaque substrate, and the material of the substrate 110 may be a quartz substrate, a glass substrate, a polymer substrate, or other suitable materials. However, the disclosure is not limited thereto. Other components required by the pixel structure 10 may also be disposed on the substrate 110, such as a driving element, a switching element, a storage capacitor, a light-emitting element, etc.

The material of the scan line SL or the data line DL may include an opaque conductive material, such as gold, silver, copper, aluminum, titanium, molybdenum, etc., an alloy thereof, or a stack of a metal or alloy material as well as other conductive materials. In some embodiments, the material of the scan line SL or the data line DL may include a transparent conductive material, such as indium tin oxide (ITO), indium zinc oxide (IZO), aluminum tin oxide, aluminum zinc oxide, indium gallium zinc oxide, or nano silver, etc., but the disclosure is not limited thereto. In some embodiments, the scan line SL or the data line DL may include a stack of an opaque conductive material and a transparent conductive material.

Referring to FIG. 2 and FIG. 3A together, the subpixel SP1 may include a transistor T1 and a transistor T2. The transistor T1 may include a conductive layer 122, a semiconductor layer 124, a dielectric layer 126, a gate 128, a gate insulating layer 130, and a source/drain 132, 134. The conductive layer 122 may be located over the substrate 110. In some embodiments, a dielectric layer 121 is disposed between the conductive layer 122 and the substrate 110. The semiconductor layer 124 may be located over the conductive layer 122. The dielectric layer 126 may be disposed between the semiconductor layer 124 and the conductive layer 122. The gate 128 may be located over the semiconductor layer 124. The gate insulating layer 130 may be disposed between the gate 128 and the semiconductor layer 124. The source/drain 132, 134 may be electrically connected with both ends of the semiconductor layer 124, respectively.

In some embodiments, the percentage of the area occupied by the conductive layer 122 of the subpixel SP1 in the subpixel SP1 is approximately 60% to 90%, such as 70% or 80%. The orthographic projection area of the semiconductor layer 124 on the substrate 110 may be substantially smaller than or equal to the orthographic projection area of the conductive layer 122 on the substrate 110. In some embodiments, the orthographic projection of the semiconductor layer 124 on the substrate 110 completely overlaps the orthographic projection of the conductive layer 122 on the substrate 110, but the disclosure is not limited thereto. In other embodiments, the orthographic projection of the semiconductor layer 124 on the substrate 110 may nearly completely overlap or partially overlap with the orthographic projection of the conductive layer 122 on the substrate 110.

In some embodiments, the semiconductor layer 124 includes a channel region C1 and heavily doped regions HD1, HD2, where the channel region C1 is located between the heavily doped regions HD1, HD2. The channel region C1 may be a region of the semiconductor layer 124 that substantially overlaps the gate 128, the heavily doped regions HD1, HD2 are respectively located on opposite sides of the channel region C1. The heavily doped regions HD1, HD2 may respectively form ohmic contact with the source/drain 132, 134, so that the source/drain 132 may be electrically connected with the channel region C1 through the heavily doped region HD1, and the source/drain 134 may be electrically connected with the channel region C1 through the heavily doped region HD2. In some embodiments, a lightly doped region LD1 is disposed between the channel region C1 and the heavily doped region HD1, and an extension region LD2 is disposed between the channel region C1 and the heavily doped region HD2. In some embodiments, the extension region LD2 may be a lightly doped region LD2. In other words, the lightly doped region LD1 and the heavily doped region HD1 are disposed on one side of the channel region C1, and the lightly doped region LD2 and the heavily doped region HD2 are disposed on the other side of the channel region C1.

In some embodiments, the pixel structure 10 further includes a dielectric layer 136, the dielectric layer 136 may cover the gate 128 and the gate insulating layer 130 of the transistor T1, and the transistor T2 may be disposed over the dielectric layer 136. In other words, the transistor T2 may be disposed on a horizontal plane higher than the transistor T1. In some embodiments, the transistor T2 completely overlaps the semiconductor layer 124 of the transistor T1 and does not overlap the gate 128 of the transistor T1.

The transistor T2 may include a conductive layer 142, a semiconductor layer 144, a dielectric layer 146, a gate 148, a gate insulating layer 150, and a source/drain 152, 154. The conductive layer 142 may be disposed over the dielectric layer 136. The semiconductor layer 144 may be disposed over the conductive layer 142. The dielectric layer 146 may be located between the semiconductor layer 144 and the conductive layer 142. The gate 148 may be disposed over the semiconductor layer 144. The gate insulating layer 150 may be located between the gate 148 and the semiconductor layer 144. The source/drain 152, 154 may be electrically connected with both ends of the semiconductor layer 144, respectively.

The orthographic projection of the conductive layer 142 on the substrate 110 may completely overlap the orthographic projection of the conductive layer 122 on the substrate 110. In some embodiments, the orthographic projection of the conductive layer 142 on the substrate 110 completely overlaps the orthographic projection of the semiconductor layer 124 on the substrate 110. The orthographic projection of the semiconductor layer 144 on the substrate 110 may completely overlap the orthographic projection of the conductive layer 122 on the substrate 110. In some embodiments, the orthographic projection of the semiconductor layer 124 on the substrate 110 completely overlaps the orthographic projection of the conductive layer 122 on the substrate 110, the orthographic projection of the conductive layer 142 on the substrate 110 completely overlaps the orthographic projection of the semiconductor layer 124 on the substrate 110, the orthographic projection of the semiconductor layer 144 on the substrate 110 completely overlaps the orthographic projection of the conductive layer 142 on the substrate 110, and the orthographic projection of the semiconductor layer 144 on the substrate 110 is located outside the orthographic projection of the gate 128 on the substrate 110. Accordingly, the semiconductor layer 144 does not overlap the step-like undulation caused by the sidewalls on the edges of the conductive layer 122, the semiconductor layer 124, the conductive layer 142, and the gate 128 on the layers thereabove. In this way, the semiconductor layer 144 can have a substantially flat surface to avoid breakage during a subsequent crystallization process.

In some embodiments, the semiconductor layer 144 includes a channel region C2 and heavily doped regions HD3, HD4, where the channel region C2 is located between the heavily doped regions HD3, HD4. The channel region C2 may be a region of the semiconductor layer 144 that substantially overlaps the gate 148, the heavily doped regions HD3, HD4 are respectively located on opposite sides of the channel region C2. The heavily doped regions HD3, HD4 may respectively form ohmic contact with the source/drain 152, 154, so that the source/drain 152 may be electrically connected with the channel region C2 through the heavily doped region HD3, and the source/drain 154 may be electrically connected with the channel region C2 through the heavily doped region HD4.

The source/drain 152, 154 may be connected with the semiconductor layer 144 by penetrating through the insulating layer 150. For example, the pixel structure 10 also includes a dielectric layer 156. The dielectric layer 156 may cover the gate 148 and the gate insulating layer 150. The source/drain 152, 154 may penetrate through the dielectric layer 156 and the gate insulating layer 150 to respectively connect to the heavily doped regions HD3, HD4 of the semiconductor layer 144. In some embodiments, through holes V3, V4 may be present in the gate insulating layer 150 and the dielectric layer 156, where the source/drain 152 may be connected with the heavily doped region HD3 of the semiconductor layer 144 through the through hole V3, and the source/drain 154 may be connected with the heavily doped region HD4 of the semiconductor layer 144 through the through hole V4.

The transistor T2 may be electrically connected with the transistor T1. For example, the source/drain 152 of the transistor T2 and the source/drain 134 of the transistor T1 may be disposed on the dielectric layer 156, and the source/drain 134, 152 may belong to the same layer and be connected with each other.

In some embodiments, the through holes V1, V2 may penetrate through the gate insulating layer 130, the dielectric layer 136, the gate insulating layer 150 and the dielectric layer 156, where the source/drain 132 may be connected with the heavily doped region HD1 of the semiconductor layer 124 from the upper surface of the dielectric layer 156 through the through hole V1, and the source/drain 134 may be connected with the heavily doped region HD2 of the semiconductor layer 124 from the upper surface of the dielectric layer 156 through the through hole V2.

In some embodiments, the dielectric layers 121, 126, 136, 146, 156 and the gate insulating layers 130, 150 may have a single-layer structure or a multi-layer structure. In some embodiments, the dielectric layers 121, 126, 136, 146, 156 and the gate insulating layers 130, 150 may include an organic or inorganic material. When any of the dielectric layers 121, 126, 136, 146, 156 and the gate insulating layers 130, 150 has a multi-layer structure, each layer in the multi-layer structure may include materials same as or different from each other. In some embodiments, at least two of the dielectric layers 121, 126, 136, 146, 156 may include the same material.

In some embodiments, the material of the semiconductor layers 124, 144 mainly includes a silicon-containing semiconductor material, such as polysilicon, microcrystalline silicon, monocrystalline silicon, amorphous silicon or silicon-rich semiconductor, but the disclosure is not limited thereto. In some embodiments, the semiconductor layers 124, 144 include indium gallium oxide (InGaO, IGO) or indium gallium zinc oxide (InGaZnO, IGZO). In some embodiments, the semiconductor layer 144 includes low temperature polysilicon (LTPS).

In some embodiments, the conductive layers 122, 142 may have a single-layer structure or a multi-layer structure. In some embodiments, the conductive layers 122, 142 may include a transparent material or a reflective material. When any of the conductive layers 122, 142 has a multi-layer structure, each layer in the multi-layer structure may include a material same as or different from each other. When any of the conductive layers 122, 142 includes a reflective material or a stack of a reflective material and a transparent material, such component may serve as another gate; or, in some embodiments, such component may serve as a light-shielding layer to shield light from outside the pixel structure 10, to prevent light from outside the pixel structure 10 from entering the semiconductor layers 124, 144. For example, the conductive layer 122 at the transistor T1 may serve as a bottom gate, and may also serve as a light-shielding layer to shield light from outside the pixel structure 10, to prevent light from outside the pixel structure 10 from entering the semiconductor layer 124. In such case, the gate 128 may serve as the top gate of the transistor T1. Similarly, when the conductive layer 144 serves as the bottom gate of the transistor T2, the conductive layer 144 may simultaneously serve as a light-shielding layer to prevent light from outside the pixel structure 10 from entering the semiconductor layer 144. At this time, the gate 148 may serve as the top gate of the transistor T2.

Referring to FIG. 2 and FIG. 3B together, the gate 128 of the subpixel SP1 may be physically connected directly with the conductive layer 122. For example, a through hole Va may be present in the dielectric layer 126 and the gate insulating layer 130, and the gate 128 may extend into the through hole Va and physically contact the conductive layer 122, Thus, the gate 128 may serve as the top gate of the transistor T1, and the conductive layer 122 may serve as the bottom gate of the transistor T1 and have the same potential as the gate 128.

Referring to FIG. 4 and FIG. 5 together, the area occupied by the subpixel SP2 of the pixel structure 10 may be the same as that of the subpixel SP1, but the disclosure is not limited thereto. In some embodiments, the area occupied by the subpixel SP2 may be different from the area occupied by the subpixel SP1. The subpixel SP2 may include the transistor T1 and the transistor T2 similar to those of the subpixel SP1, and the percentage of the area occupied by the conductive layer 122 of the transistor T1 of the subpixel SP2 in the subpixel SP2 may be different from the percentage of the area occupied by the conductive layer 122 of the transistor T1 of the subpixel SP1 in the subpixel SP1. In some embodiments, the percentage of the area occupied by the conductive layer 122 of the transistor T1 of the subpixel SP2 in the subpixel SP2 is greater than the percentage of the area occupied by the conductive layer 122 of the transistor T1 of the subpixel SP1 in the subpixel SP1. For example, the percentage of the area occupied by the conductive layer 122 of the transistor T1 of the subpixel SP1 in the subpixel SP1 is about 70% to 90%, while the percentage of the area occupied by the conductive layer 122 of the transistor T1 of the subpixel SP2 in the subpixel SP2 is about 50% to 70%.

Since the percentage of the area occupied by the conductive layer 122 of the subpixel SP2 in the subpixel SP2 is about 50% to 70%, in the area not occupied by the conductive layer 122, a transfer conductive layer 123 belonging to the same layer as the conductive layer 122 may be additionally disposed to provide an additional conductive wire connection function, and the transfer conductive layer 123 and the conductive layer 122 may be physically separated from each other. For example, the subpixel SP2 may further include a transfer conductive layer 143, the transfer conductive layer 143 may belong to the same layer as and be physically separated from each other from the conductive layer 142. Additionally, a through hole V5 may be present in the dielectric layer 126, the gate insulating layer 130, the dielectric layer 136, the dielectric layer 146, the gate insulating layer 150, and the dielectric layer 156, and a through hole V6 may be present in the dielectric layer 146, the gate insulating layer 150, and the dielectric layer 156. The transfer conductive layer 143 may be electrically connected with the transfer conductive layer 123 through the through hole V6, a connector 163 located on the dielectric layer 156, and the through hole V5. In some embodiments, the percentage of the area occupied by the transfer conductive layer 123 in the subpixel SP2 is 5% to 15%. In some embodiments, the connector 163 may belong to the same layer as the source/drain 132, 134. In some embodiments, the connector 163 may be electrically connected with the source/drain 132, 134 (not shown).

In some embodiments, the subpixel SP3 of the pixel structure 10 may have substantially the same structure as the subpixel SP2, but the disclosure is not limited thereto. In some embodiments, in an orthographic projection direction toward the substrate 110, the percentages of the areas occupied by the conductive layers 122 of at least two of the subpixels SP1, SP2, SP3 in the respective subpixels are different. For example, the percentage of the area occupied by the conductive layer 122 of the subpixel SP1 in the subpixel SP1 is different from the percentage of the area occupied by the conductive layer 122 of the subpixel SP2 in the subpixel SP2 and/or the percentage of the area occupied by the conductive layer 122 of the subpixel SP3 in the subpixel SP3. More specifically, the percentage of the area occupied by the conductive layer 122 of the subpixel SP3 in the subpixel SP3 may be equal to (the orthographic projection area of the conductive layer 122 of the subpixel SP3 on the substrate 110)/(the orthographic projection area of the subpixel SP3 on the substrate 110)*100%. The same applies to other subpixels.

The pixel structure 10 may also include multiple light-emitting elements 170, which are respectively disposed in the subpixels SP1, SP2, SP3, and are respectively electrically connected with the transistor T1 or the transistor T2. For example, the light-emitting element 170 may be an inorganic self-emitting element, an organic self-emitting element, or other suitable elements. In some embodiments, the pixel structure 10 further includes a planarization layer 158, an insulating layer 160, a planarization layer 162, and an insulating layer 164 sequentially stacked on the dielectric layer 156, and a conductive wire 161 located on the upper surface of the insulating layer 160. In addition, a through hole Vb is present in the planarization layer 158 and the insulating layer 160, a through hole Vc is present in the planarization layer 162 and the insulating layer 164, and an end of the conductive wire 161 is electrically connected with the through hole Vb, the other end of the conductive wire 161 is electrically connected with the through hole Vc, the light-emitting element 170 may be disposed on the insulating layer 164, and an electrode 172 of the light-emitting element 170 may be electrically connected with the source/drain 154 of the transistor T2 through the through hole Vc, the conductive wire 161, and the through hole Vb. In some embodiments, the pixel structure 10 further includes an optical layer 166 covering the light-emitting element 170. In some embodiments, the optical layer 166 includes multiple layers, such as a polarizer, an anti-glare film, an anti-reflection film, or other suitable optical films.

The material of the planarization layers 158, 162 may include an organic material, such as acrylic material, siloxane material, polyimide material, epoxy material, or a stack of thereof. However, the disclosure is not limited thereto. The material of the insulating layers 160, 164 may include an inorganic material, such as silicon oxide, silicon nitride, silicon oxynitride, or a stack thereof. However, the disclosure is not limited thereto.

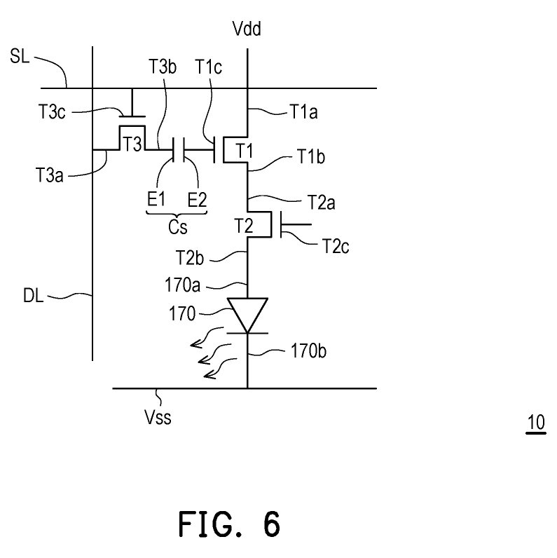

FIG. 6 is a schematic diagram of a pixel circuit of the subpixel SP of the pixel structure 10 according to an embodiment of the disclosure. At least one of the subpixel SP1, the subpixel SP2, and the subpixel SP3 of the pixel structure 10 may adopt the pixel circuit shown in FIG. 6. Referring to FIG. 6, in some embodiments, the subpixel SP has a 3T1C circuit structure. For example, the subpixel SP may include the transistor T1, the transistor T2, the transistor T3, a capacitor Cs, and the light-emitting element 170. A first terminal T3a of the transistor T3 may be coupled to the data line DL, a control terminal T3c of the transistor T3 may be coupled to the scan line SL, a second terminal T3b of the transistor T3 may be coupled to a first terminal E1 of the capacitor Cs, a second terminal E2 of the capacitor Cs may be coupled to a control terminal T1c of the transistor T1, a first terminal T1a of the transistor T1 may be coupled to a power line Vdd to receive, for example, a system high voltage, a second terminal T1b of the transistor T1 may be coupled to a first terminal T2a of the transistor T2, a control terminal T2c of the transistor T2 may receive a control signal, a second terminal T2b of the transistor T2 may be coupled to a first terminal 170a of the light-emitting element 170, a second terminal 170b of the light-emitting element 170 may be coupled to a power line Vss to receive, for example, a system voltage different from that provided by the power line Vdd. The signal transmitted on the scan line SL may control the transistor T3 to write the data transmitted on the data line DL into the capacitor Cs. The transistor T3 may control the charging time of the capacitor Cs, and the capacitor Cs may stabilize the voltage at the control terminal T1c of the transistor T1. The transistor T1 may serve as a driving element or an emitting controller for performing voltage-to-current conversion to drive the light-emitting element 170 to emit light and control the current entering the light-emitting element 170, and the transistor T2 may serve as a switch element to control the emission time of the light-emitting element 170.

In some embodiments, in the subpixel SP2 and the subpixel SP3, the gate 128 of the transistor T1 may partially overlap the conductive layer 122, partially overlap the transfer conductive layer 123, and partially overlap the transfer conductive layer 123. In some embodiments, in the subpixel SP2 and the subpixel SP3, the portion where the gate 128 overlaps the transfer conductive layer 143 may form the capacitor Cs.

In some embodiments, the power line Vdd is parallel to the data line DL. In some embodiments, the power line Vss is parallel with the scan line SL. In some embodiments, the power line Vdd and the data line DL are alternately disposed on the substrate 110 along the direction D1. In some embodiments, the power line Vss and the scan line SL are alternately disposed on the substrate 110 along the direction D2. In some embodiments, two adjacent scan lines SL are interlaced with the adjacent data line DL and power line Vdd to define a region for disposing one subpixel SP. In some embodiments, two adjacent data lines DL are interlaced with the adjacent scan line SL and power line Vss to define a region for disposing one subpixel SP. In some embodiments, the adjacent data line DL and power line Vdd are interlaced with the adjacent scan line SL and power line Vss to define a region for disposing one subpixel SP.

In some embodiments, the subpixel SP of the pixel structure 10 may have an nTmC circuit structure, where n>1, m>1, and n is not equal to m. For example, the pixel structure 10 may have a circuit structure such as 2T1C, 3T1C, 4T1C, 5T1C, 6T1C, 7T1C, 4T2C, 5T2C, 6T2C or 7T2C.

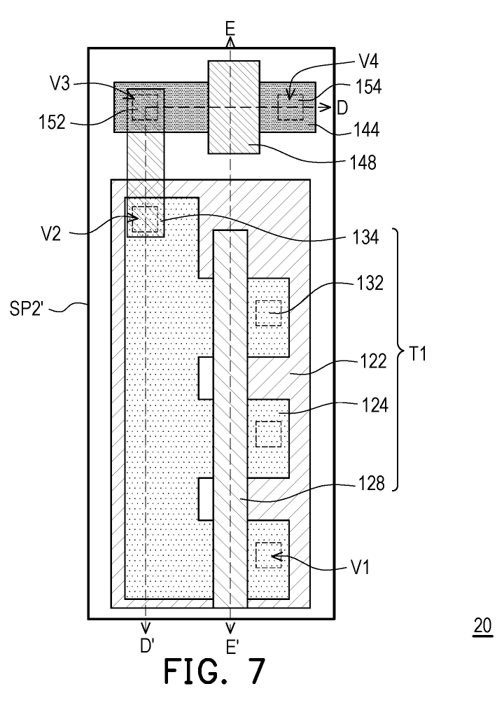

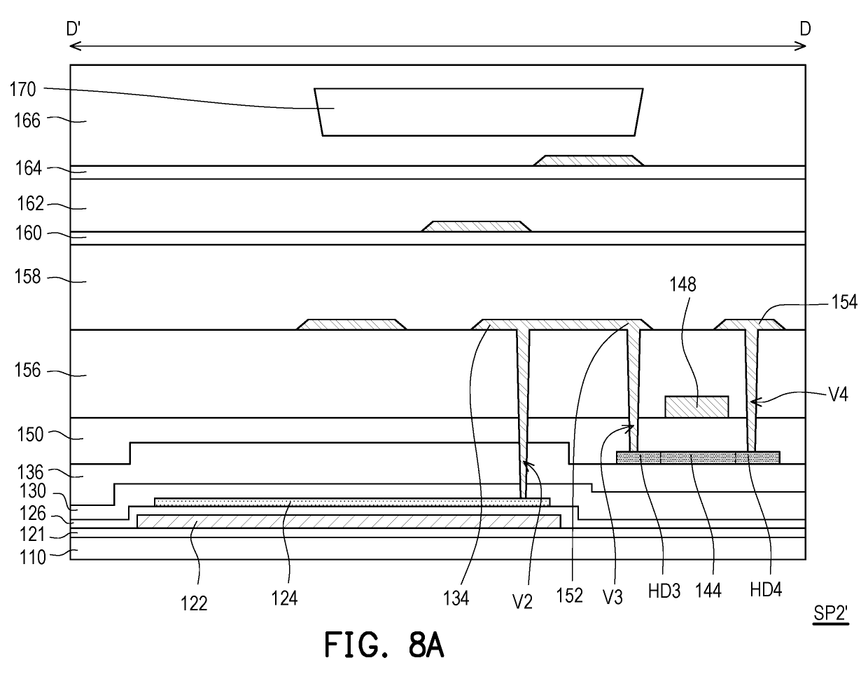

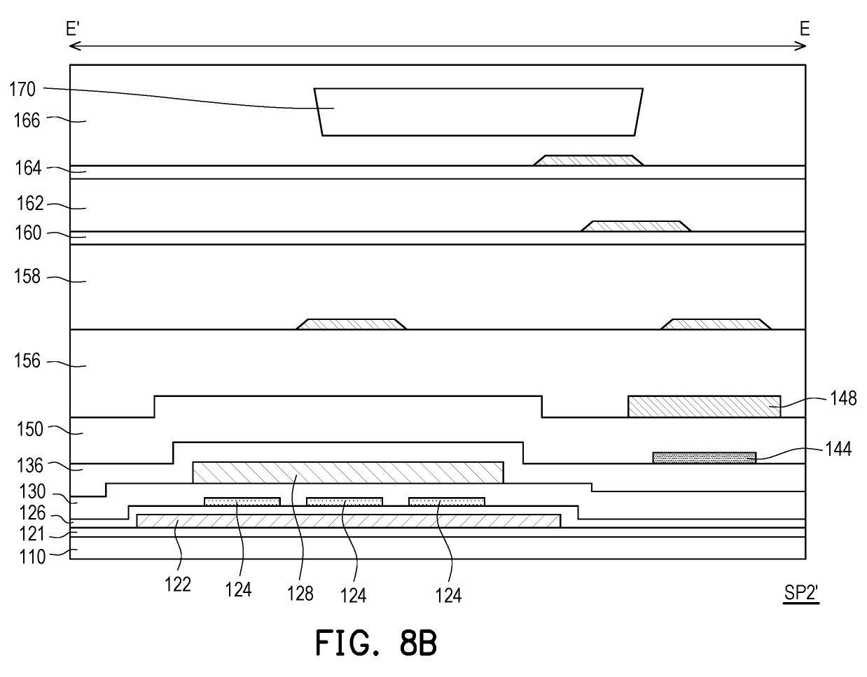

FIG. 7 is an enlarged schematic view of a second subpixel SP2' of a pixel structure 20 according to another embodiment of the disclosure. FIG. 8A is a schematic cross-sectional view taken along a cross-sectional line D-D' of FIG. 7. FIG. 8B is a schematic cross-sectional view taken along a cross-sectional line E-E' of FIG. 7.

Referring to FIG. 7, FIG. 8A, and FIG. 8B together, a second subpixel SP2' of the pixel structure 20 may include the transistor T1, the transistor T2 and the light-emitting element 170. The transistor T1 of the second subpixel SP2' may include the conductive layer 122, the semiconductor layer 124, the dielectric layer 126, the gate 128, the gate insulating layer 130, and the source/drain 132, 134. The percentage of the area occupied by the conductive layer 122 in the subpixel SP2' may be approximately 50% to 70%, the semiconductor layer 124 may completely overlap the conductive layer 122, the dielectric layer 126 is located between the conductive layer 122 and the semiconductor layer 124, the gate 128 completely overlaps the conductive layer 122 and partially overlaps the semiconductor layer 124, and the gate insulating layer 130 is located between the gate 128 and the semiconductor layer 124.

In the second subpixel SP2', the dielectric layer 136 may cover the transistor T1, and the transistor T2 of the second subpixel SP2' may be disposed on the dielectric layer 136. The transistor T2 may be disposed in a region of the second subpixel SP2' not occupied by the transistor T1. In other words, it may also be that the transistor T2 of the second subpixel SP2' does not overlap the transistor T1. In addition, the light-emitting element 170 may be disposed over the transistors T1, T2 and partially overlap the transistor T1 and the transistor T2. In some embodiments, the light-emitting element 170 may be electrically connected with the transistor T1 or the transistor T2.

For example, the transistor T2 of the second subpixel SP2' may include the semiconductor layer 144, the gate 148, the gate insulating layer 150, and the source/drain 152, 154. The gate insulating layer 150 is located between the gate 148 and the semiconductor layer 144. In the second subpixel SP2', the orthographic projection of the gate 148 on the substrate 110 does not overlap the orthographic projections of the conductive layer 122 and the semiconductor layer 124 on the substrate 110, and the orthographic projection of the semiconductor layer 144 on the substrate 110 does not overlap the orthographic projections of the conductive layer 122 and the semiconductor layer 124 on the substrate 110, either. In some embodiments, the percentage of the area occupied by the semiconductor layer 144 in the subpixel SP2' may be approximately 5% to 15%.

In addition, in the second subpixel SP2', the dielectric layer 156 may cover the gate 148 and the gate insulating layer 150, the through holes V3, V4 may be present in the gate insulating layer 150 and the dielectric layer 156, and the source/drain 152, 154 may be connected from the upper surface of the dielectric layer 156 to the heavily doped regions HD3, HD4 of the semiconductor layer 144 along the through holes V3, V4, respectively. Furthermore, the source/drain 134 of the transistor T1 may be located on the upper surface of the dielectric layer 156 and physically connected with the source/drain 152, and the source/drain 134 may be connected from the upper surface of the dielectric layer 156 to the semiconductor layer 124 along the through hole V2 present in the gate insulating layer 130, the dielectric layer 136, the gate insulating layer 150, and the dielectric layer 156.

In some embodiments, the pixel structure 20 may further include a first subpixel and a third subpixel (not shown), and the first subpixel may have the same structure as the subpixel SP1 of the pixel structure 10. In some embodiments, the third subpixel of the pixel structure 20 has the same structure as the second subpixel SP2' of the pixel structure 20. In some embodiments, the third subpixel of the pixel structure 20 has the same structure as the subpixel SP2 of the pixel structure 10.

Based on the above, by arranging the semiconductor layer of the upper transistor to completely overlap the conductive layer of the lower transistor and not overlap the gate of the lower transistor, or arranging the semiconductor layer of the upper transistor to not overlap the conductive layer of the lower transistor and not overlap the gate of the lower transistor, the pixel structure of the disclosure prevents the semiconductor layer of the upper transistor from breaking during a subsequent crystallization process. As a result, the yield rate of the pixel structure is increased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pixel structure, disposed on a substrate, the pixel structure comprising:
a first transistor, comprising:
a first conductive layer, located over the substrate;
a first semiconductor layer, located over the first conductive layer;
a first dielectric layer, located between the first semiconductor layer and the first conductive layer;
a first gate, located over the first semiconductor layer;
a first gate insulating layer, located between the first gate and the first semiconductor layer; and
a first source/drain, electrically connected with the first semiconductor layer; and
a second transistor, electrically connected with the first transistor and comprising:
a second semiconductor layer, located over the first semiconductor layer;
a second gate, located over the second semiconductor layer;
a second gate insulating layer, located between the second gate and the second semiconductor layer; and
a second source/drain, electrically connected with the second semiconductor layer,
wherein an orthographic projection of the second semiconductor layer on the substrate completely overlaps an orthographic projection of the first conductive layer on the substrate, and the orthographic projection of the second semiconductor layer on the substrate is located outside an orthographic projection of the first gate on the substrate.

2. The pixel structure as claimed in claim 1, wherein the second semiconductor layer comprises polysilicon, microcrystalline silicon, monocrystalline silicon, amorphous silicon or silicon-rich semiconductor.

3. The pixel structure as claimed in claim 1, wherein the first gate is physically connected directly with the first conductive layer.

4. The pixel structure as claimed in claim 1, wherein a horizontal height of the second semiconductor layer is higher than a horizontal height of the first semiconductor layer.

5. The pixel structure as claimed in claim 1, wherein an orthographic projection of the first semiconductor layer on the substrate completely overlaps the orthographic projection of the first conductive layer on the substrate.

6. The pixel structure as claimed in claim 1, further comprising:
a transfer conductive layer, belonging to a same layer as the first conductive layer and physically separated from the first conductive layer.

7. The pixel structure as claimed in claim 1, further comprising:
a data line, electrically connected with the first source/drain; and
a scan line, electrically connected with the first gate,
wherein the scan line intersects the data line.

8. The pixel structure as claimed in claim 7, further comprising:
a first power line, parallel to the data line; and
a second power line, parallel to the scan line.

9. A pixel structure, comprising:
a substrate;
a plurality of subpixels, disposed on the substrate, wherein each of the subpixels comprises:
a first transistor, comprising:
a first conductive layer, located over the substrate;
a first semiconductor layer, located over the first conductive layer;
a first dielectric layer, located between the first semiconductor layer and the first conductive layer;
a first gate, located over the first semiconductor layer;
a first gate insulating layer, located between the first gate and the first semiconductor layer; and
a first source/drain, electrically connected with the first semiconductor layer,
wherein an orthographic projection area of the first semiconductor layer on the substrate is substantially smaller than or equal to an orthographic projection area of the first conductive layer on the substrate; and
a second transistor, located over the first transistor and electrically connected with the first transistor, wherein the second transistor comprises:
a second conductive layer, located over the first semiconductor layer;
a second semiconductor layer, located over the second conductive layer;
a second dielectric layer, located between the second semiconductor layer and the second conductive layer;
a second gate, located over the second semiconductor layer;
a second gate insulating layer, located between the second gate and the second semiconductor layer; and
a second source/drain, electrically connected with the second semiconductor layer,
wherein a percentage of an area occupied by the first conductive layer of a first subpixel among the subpixels in the first subpixel is different from a percentage of an area occupied by the first conductive layer of a second subpixel among the subpixels in the second subpixel; and
a plurality of light-emitting elements, respectively disposed in the subpixels and respectively electrically connected with the first transistor or the second transistor.

10. The pixel structure as claimed in claim 9, wherein the percentage of the area occupied by the first conductive layer of the first subpixel in the first subpixel is 60% to 90%.

11. The pixel structure as claimed in claim 9, wherein the percentage of the area occupied by the first conductive layer of the second subpixel in the second subpixel is 50% to 70%.

12. The pixel structure as claimed in claim 9, wherein an orthographic projection of the second semiconductor layer on the substrate completely overlaps the orthographic projection of the first conductive layer on the substrate, and the orthographic projection of the second semiconductor layer on the substrate does not overlap an orthographic projection of the first gate on the substrate.

13. The pixel structure as claimed in claim 12, wherein the orthographic projection of the second semiconductor layer on the substrate completely overlaps the orthographic projection of the first semiconductor layer on the substrate.

14. The pixel structure as claimed in claim 13, wherein the orthographic projection of the first semiconductor layer on the substrate completely overlaps the orthographic projection of the first conductive layer on the substrate.

15. The pixel structure as claimed in claim 9, wherein an orthographic projection of the second semiconductor layer on the substrate does not overlap the orthographic projection of the first conductive layer on the substrate.

16. The pixel structure as claimed in claim 9, further comprising:
a plurality of first wires parallel to each other, respectively located between two adjacent subpixels; and
a plurality of second wires parallel to each other, respectively located between two adjacent subpixels and intersecting the first wires.

17. The pixel structure as claimed in claim 16, wherein the first wires comprise a data line and a first power line, the second wires comprise a gate line and a second power line, the first power line is different from the second power line, and the second power line is electrically connected with the light-emitting element.

18. The pixel structure as claimed in claim 9, further comprising:
a first transfer conductive layer, located in the second subpixel, belonging to a same layer as the first conductive layer, and physically separated from the first conductive layer; and
a second transfer conductive layer, located in the second subpixel, belonging to a same layer as the second conductive layer, and physically separated from the second conductive layer,
wherein the second transfer conductive layer overlaps the first transfer conductive layer, and
wherein the second transfer conductive layer is electrically connected with the first transfer conductive layer.

19. The pixel structure as claimed in claim 18, wherein a percentage of an area occupied by the first transfer conductive layer or the second transfer conductive layer in the second subpixel is 5% to 15%.

20. The pixel structure as claimed in claim 9, wherein the first subpixel emits red light, and the second subpixel emits blue light or green light.
